(19) United States
(12) Patent Application Publication
(10) Pub. No.: US 2005/0160351 A1
(43) Pub. Date: Jul. 21, 2005

(54) Method of forming parity check matrix for parallel concatenated LDPC code

(76) Inventors: Young Jo Ko, Daejeon-shi (KR); Jung Hoon Kim, Daejeon-shi (KR)

Correspondence Address: MAYER, BROWN, ROWE & MAW LLP, 1909 K STREET, N.W., WASHINGTON, DC, 20006, US

(21) Appl. No.: 11/006,723

(22) Filed: Dec. 8, 2004

(30) Foreign Application Priority Data
Dec. 26, 2003 (KR) 2003-97060
Aug. 24, 2004 (KR) 2004-66627

(51) Int. Cl. H03M 13/00; G06F 11/00

(52) U.S. Cl. 714/801

(57) ABSTRACT

Provided is a method of forming a parity-check matrix for a parallel concatenated LDPC code, wherein the parallel concatenated LDPC code is composed of a first LDPC code, a second LDPC code, and an interleaver connecting therebetween. The method includes: the steps of (a) finding a degree distribution of a first LDPC code and a degree distribution of a second LDPC; and (b) forming the parity-check matrices of the first and second LDPC codes satisfying the degree distributions, wherein in the (a) step, the degree distributions of the first and second LDPC codes are found using performance measurement by a density evolution method, and wherein in the density evolution method, the probability density of a message forwarded from a variable node of the first LDPC code to a check node reflects a probability density of extrinsic information outputted from the second LDPC code, and the probability density of a message forwarded from a variable node of the second LDPC code to a check node reflects a probability density of extrinsic information outputted from the first LDPC code.

### CROSS-REFERENCE TO RELATED APPLICATION

This application claims priority to and the benefit of Korean Patent Application Nos. 2003-97060, filed on Dec. 26, 2003 and 2004-66627. filed on Aug. 24, 2004, the disclosure of which is incorporated herein by reference in its entirety.

### BACKGROUND

1. Field of the Invention

The present invention relates to a channel coding technique of detecting and correcting errors of data in a wireless communication system and, more particularly, to a method of forming parity-check matrices for parallel concatenated low-density parity-check (LDPC) codes, which has good performance by concatenating in parallel the LDPC codes.

2. Description of the Related Art

Much effort has been made to use an LDPC code as a channel code. The LDPC code introduced by Gallager for the first time has been forgotten for a long time. However, recently, with an increasing interest in Turbo codes, codes on graphs etc., the LDPC code has been rediscovered by Mackay and Neal, and proved to be an excellent code with performance close to channel capacity. This related information is well disclosed in “Low Density Parity Check Codes, MIT Press, Cambridge, Mass., 1963, R. G. Gallager and Near Shannon Limit Performance of Low Density Parity Checks Codes, Electron. Lett., vol. 33, no. 6, pp. 457-458, March 1997, D. J. C Mackay and R. M. Neal.” Especially, Richardson et al. presented a density evolution method for analyzing performance of regular and irregular LDPC codes. This method makes it possible to analyze performance of the LDPC code having an infinite block length, so that the optimization of degree distributions for infinite-length LI)PC codes became possible. This is well disclosed in “Design of Capacity-Approaching Irregular Low-Density Parity-Check Codes, IEEE Trans. Inform. Theory, vol. 47, pp. 619-637, February 2001, T. J. Richardson, M. A. Shokrollahi and R. L. Urbanke.” The density evolution method describes the average performance of an LDPC code ensemble specified by degree distributions of variable and check nodes. In terms of parity-check matrices, the code ensemble is generated on the assumption that the number of 1's. included in each column and row of the parity-check matrix follows a given degree distribution and that the position of 1's is chosen randomly.

A parallel concatenated LDPC code has a structure in which two LDPC codes are connected to each other with an interleaver interposed between them. Each LDPC code is independently described by its own degree distributions for variable and check nodes.

### SUMMARY OF THE INVENTION

Therefore, the present invention is directed to the performance analysis of a parallel concatenated code with two or more component LDPC codes, and the design of such a concatenated code with an optimal performance. Specifically, the present invention is directed to providing a method of analyzing the performance of an infinite-length parallel concatenated LDPC code in order to design a parallel concatenated LDPC code having optimal performance, and furthermore a method of constructing a finite length code with optimal performance.

To accomplish the above-mentioned objectives, one aspect of the present invention is to provide a method of forming a parity-check matrix for a parallel concatenated LDPC code, wherein the parallel concatenated LDPC code is composed of a first LDPC code, a second LDPC code, and an interleaver connected therebetween. The method includes: the steps of (a) finding a degree distribution of a first LDPC code and a degree distribution of a second LDPC code; and (b) forming the parity-check matrices of the first and second LDPC codes satisfying the degree distributions. In step (a), the degree distributions of the first and second LDPC codes are found by using a density evolution method. In the density evolution method, the probability density of a message outgoing from a variable node of the first LDPC code to a check node includes the probability density of extrinsic information outputted from the second LDPC code. Further, the probability density of a message outgoing from a variable node of the second LDPC code to a check node includes the probability density of extrinsic information outputted from the first LDPC code.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a schematic block diagram showing an encoder for the parallel concatenated LDPC code;

FIG. 2 is a schematic block diagram showing an decoder for the parallel concatenated LDPC code;

FIG. 3 is a conceptual diagram representing the parallel concatenated LDPC decoder of FIG. 2 using a bipartite graph;

FIG. 4 is a diagram showing a parity-check matrix of lower triangular form;

FIG. 5 is a graph showing simulation results on the assumption that an LDPC code having a code rate of 1/2 and a code word length of 1000 bits is subjected to BPSK modulation and is assigned an AWGN channel;

FIG. 6 is a graph showing simulation results on the assumption that an LDPC code having a code rate of 1/3 and a code word length of 1500 bits is subjected to BPSK modulation and is assigned an AWGN channel;

FIG. 7 is a graph showing simulation results on the assumption that an LDPC code having a code rate of 1/4 and a code word length of 2000 bits is subjected to BPSK modulation and is assigned an AWGN channel; and

FIG. 8 is a flow chart showing a method of forming a parity-check matrix for a parallel concatenated LDPC code in accordance with one embodiment of the present invention.

### DETAILED DESCRIPTION OF THE INVENTION

Hereinafter, a theoretical concept of the present invention will be described with reference to the attached drawings.

1. LDPC Encoding Process

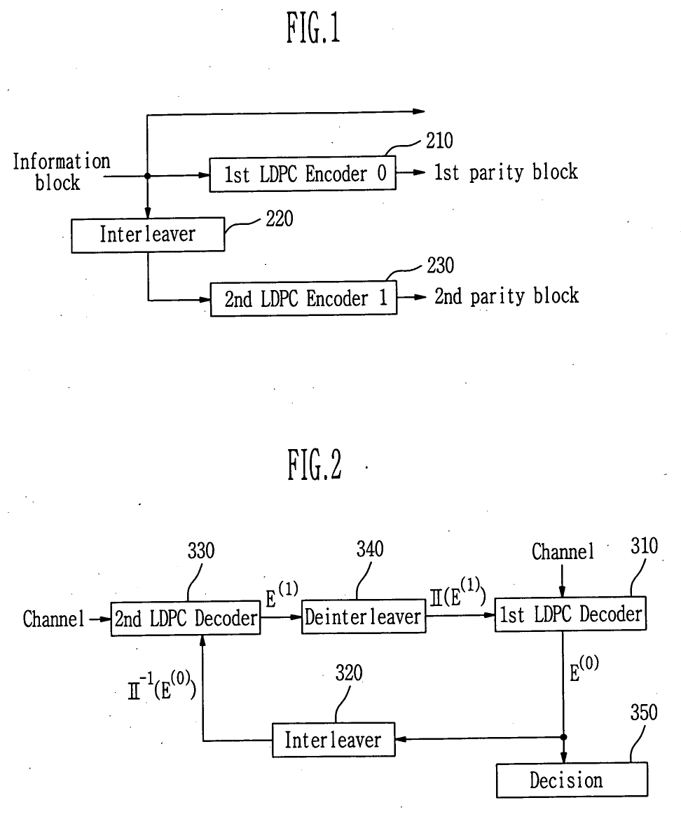

The encoding process will be described with reference to FIG. 1. FIG. 1 is a schematic block diagram showing a parallel concatenated LDPC encoder. Referring to FIG. 1, the parallel concatenated LDPC encoder includes a first LDPC encoder 210, an interleaver 220, and a second LDPC encoder 230. Each of the first and second LDPC encoders 210 and 230 encodes data inputted to the LDPC encoders and outputs the LDPC encoded data. The interleaver 220 interleaves the inputted data, that is, randomly permutes the order of the inputted data, and outputs the interleaved data.

Each parallel concatenated LDPC encoder branches an information block, which is the inputted data, into three information sub-blocks. The first information sub-block is modulated and forwarded to a designated channel. The second information sub-block obtains a first parity block by means of the first LDPC encoder 210 and then is modulated and forwarded to a designated channel. The third information sub-block obtains a second parity block by means of the second LDPC encoder 230 and then is modulated and forwarded to a designated channel.

2. LDPC Decoding Process

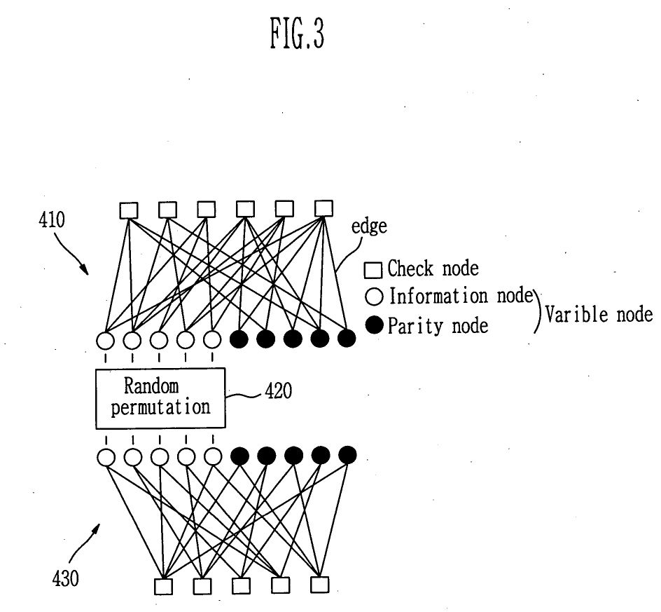

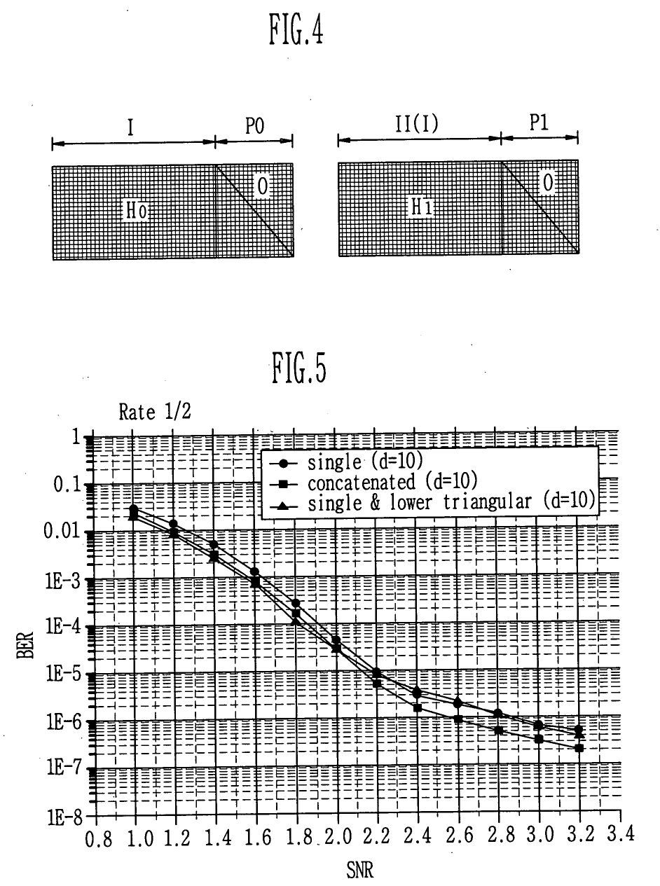

The decoding process will be described with reference to FIGS. 2 and 3. FIG. 2 is a schematic block diagram showing a parallel concatenated LDPC decoder. FIG. 3 is a conceptual diagram representing the parallel concatenated LDPC decoder of FIG. 2 using bipartite graphs. Referring to FIG. 2, the parallel concatenated LDPC decoder includes a first LDPC decoder 310, an interleaver 320, a second LDPC decoder 330, a deinterleaver 340 and a decision unit 350. The first and second LDPC decoders 310 and 330 perform iterative decoding using a belief propagation algorithm. The interleaver 320 changes the order of data, and the deinterleaver 340 restores the data order changed by the interleaver 320 to the original one. The decision unit 350 decides what a value of the information block inputted into the LDPC decoder is. Referring FIG. 3, a bipartite graph 410 of the first LDPC decoder is composed of check nodes, variable nodes, and edges, wherein the edges connect the check and variable nodes. The variable nodes are composed of information nodes and parity nodes. A bipartite graph 430 of the second LDPC decoder also has the same configuration as that of the first LDPC decoder. The interleaver 320 and the deinterleaver 340 shown in FIG. 2 are indicated by a reference number 420 which indicates a random permutation. Through this random permutation, the information nodes of the first bipartite graph 410 are interconnected with those of the second bipartite graph 430.

Referring to FIG. 2, the LDPC decoders 310 and 330, both of which serve as a posteriori probability (APP) decoder similar to a Turbo decoder, provide a log-likelihood ratio (LLR) of information bits to each other.

Each of the LDPC decoders 310 and 330 performs the iterative decoding using a belief propagation algorithm. Each of the LDPC decoders 310 and 330 receives extrinsic information forwarded from a different decoder via the interleaver 320 or the deinterleaver 340 whenever the iterative decoding is performed, and produces new extrinsic information. Then, each LDPC decoder forwards the new extrinsic information to the different decoder via the deinterleaver 340 or the interleaver 320. Each iterative decoding is sequentially performed in the order of variable node update, check node update, and extrinsic information generation.

A decoding process of the first LDPC decoder 310 is as follows.

First, extrinsic information E⁽¹⁾ is received from the second LDPC decoder as an input.

Second, a variable node message is updated. Specifically, a message v⁽⁰⁾ which is transmitted from the variable node to the check node via an edge e is found as follows. That is, when the variable node has a degree of dᵥ and corresponds to the information node, the message v^{(O)} is expressed as Equation 1, where the extrinsic information E⁽¹⁾ is added. When the variable node corresponds to the parity node, the message v⁽⁰⁾ is expressed as Equation 2.

$$\begin{matrix}{v}^{( 0 )} = {\sum }_{i = 0}^{{d}_{v} - 1} {u}_{i}^{( 0 )} + {E}^{( 1 )} & Equation 1 \\ {v}^{( 0 )} = {\sum }_{i = 0}^{{d}_{v} - 1} {u}_{i}^{( 0 )} & Equation 2\end{matrix}$$

where uᵢ⁽⁰⁾ (i=0), i.e. u₀⁽⁰⁾, denotes an initial LLR value of a code word bit corresponding to the variable node, and may be obtained from a channel output, and uᵢ⁽⁰⁾ (i=1, 2, . . . , dᵥ−1) denotes LLR messages forwarded from the check nodes through all the other edges excluding the edge e from the edges connected to the variable node.

Third, a check node message is updated. Specifically, when the message transmitted from a check node having a degree of d_{c} to the variable node through the edge e is defined as u⁽⁰⁾, u⁽⁰⁾ is updated from {vᵢ⁽⁰⁾} by applying a decoding rule of tan h in Equation 3.

$$tanh \frac{{u}^{( 0 )}}{2} = {\prod }_{i = 1}^{{d}_{c} - 1} tanh \frac{{v}_{i}^{( 0 )}}{2} \qquad Equation 3$$

where vᵢ⁽⁰⁾ (i=1, 2, . . . , d_{c}⁽⁰⁾−1) denotes LLR messages forwarded from the variable nodes through all the other edges excluding the edge e from the edges connected to the check node.

Fourth, the extrinsic information is produced. Specifically, the extrinsic information on each information node is calculated from the updated {uᵢ⁽⁰⁾} as Equation 4.

$${E}^{( 0 )} = {\sum }_{i = 1}^{{d}_{v}} {u}_{i}^{( 0 )} \qquad Equation 4$$

where uᵢ⁽⁰⁾ (i=1, 2, . . . , dᵥ) denotes LLR messages forwarded through all the edges connected to the information node having a degree of dᵥ.

The second LDPC decoder 330, as a posteriori probability (APP) decoder, performs the iterative decoding using a belief propagation algorithm. The second LDPC decoder 330 receives extrinsic information Π⁻¹ (E⁽⁰⁾), which is forwarded from the first LDPC decoder 310 via the interleaver 320, as an input whenever the iterative decoding is performed, and produces new extrinsic information E⁽¹⁾. Then, the second LDPC decoder 330 forwards the new extrinsic information E⁽¹⁾ to the first LDPC decoder 310 via deinterleaver 340. Each iterative decoding is sequentially performed in the order of variable node update, check node update, and extrinsic information generation.

The second LDPC decoder 330, also, has a decoding process which is similar to that of the first LDPC decoder 310 and is as follows.

First, extrinsic information E⁽⁰⁾ produced from the first LDPC decoder 310 is received as an input.

Second, a variable node message is updated. Specifically, a message v⁽¹⁾, which is transmitted from the variable node to the check node through the edge e, is found as follows. That is, when the variable node has a degree of dᵥ and corresponds to the information node, the message v⁽¹⁾ is expressed as Equation 5, where the extrinsic information E₍₀₎ is added. When the variable node corresponds to the parity node, the message v⁽¹⁾ is expressed as Equation 6.

$$\begin{matrix}{v}^{( 1 )} = {\sum }_{i = 0}^{{d}_{v} - 1} {u}_{i}^{( 1 )} + {E}_{( 0 )} & Equation 5 \\ {v}^{( 1 )} = {\sum }_{i = 0}^{{d}_{v} - 1} {u}_{i}^{( 1 )} & Equation 6\end{matrix}$$

where uᵢ⁽¹⁾ (i=0), i.e. u₀⁽¹⁾, denotes an initial LLR value of a code word bit corresponding to the variable node and may be obtained from a channel output, and uᵢ⁽¹⁾ (i=1, 2, . . . , dᵥ−1) denotes LLR messages forwarded from the check nodes through all the other edges excluding the edge e from the edges connected to the variable node.

Third, a check node message is updated. Specifically, when the message transmitted from a check node having a degree of d_{c} to the variable node through the edge e is defined as u⁽¹⁾, u⁽¹⁾ is updated from {vᵢ⁽¹⁾} from a decoding rule of tan h in Equation 7.

$$tanh \frac{{u}^{( 1 )}}{2} = {\prod }_{i = 1}^{{d}_{c} - 1} tanh \frac{{v}_{i}^{( 1 )}}{2} \qquad Equation 7$$

where, vᵢ⁽¹⁾ (i=1, 2, . . . , d_{c}⁽¹⁾−1) denotes LLR messages forwarded from the variable nodes through all the other edges excluding the edge e from the edges connected to the check node.

Fourth, extrinsic information is produced. Specifically, the extrinsic information on each information node is calculated from the updated {uᵢ⁽¹⁾} as Equation 8.

$${E}^{( 1 )} = {\sum }_{i = 1}^{d} {u}_{i}^{( 1 )} \qquad Equation 8$$

where, uᵢ⁽¹⁾ (i=1, 2, . . . , dᵥ) denotes LLR messages forwarded through all the edges connected to the information node having a degree of dᵥ.

When a code bit is defined as x and it is assumed that BPSK modulation where a signal point is given as w=(1-2x) is performed and that an AWGN channel is assigned, a received signal y on a receipt side has a probability density function as Equation 9.

$$p ( y \vert w ) = \frac{1}{\sqrt{2 {πσ}^{2}}} exp ( - \frac{{( y - w )}^{2}}{2 {σ}^{2}} ) \qquad Equation 9$$

where σ²=(1/2R·(E_{b}/N₀)) denotes a noise variance, R denotes a code rate. Assuming that Pr(x=0)=Pr(x=1), an initial LLR value of the code bit x obtained from a channel output is expressed as Equation 10.

$${u}_{0} = ln \frac{P ( x = 0 \vert y )}{P ( x = 1 \vert y )} = \frac{2}{{σ}^{2}} y \qquad Equation 10$$

Further, under the assumption that all 0 (zero)-codeword has been transmitted, the probability density function of u₀ is expressed as Equation 11.

$${P}_{0} ( {u}_{0} ) = \frac{σ}{2 \sqrt{2 π}} exp ( - \frac{{( {u}_{0} - \frac{2}{{σ}^{2}} )}^{2}}{8 / {σ}^{2}} ) \qquad Equation 11$$

3. Density Evolution of a Parallel Concatenated LDPC Code

First of all, a density evolution method for a regular LDPC code of the second LDPC decoder will be described below.

It is assumed that a variable node of the second LDPC decoder has a degree of d⁽¹⁾ᵥ and is connected to a variable node of the first LDPC decoder having a degree of d⁽⁰⁾ᵥ, wherein an interleaver is interposed between the first and second LDPC decoders. The probability density Pᵥ⁽¹⁾ of a message v transmitted from the variable node to a check node is found as Equation 12.
P_{v,inf}⁽¹⁾=P₀ (in the first iteration) Equation 12
P_{v,inf}⁽¹⁾=P₀\mathring{X}Pᵢₙ⁽¹⁾\mathring{X}Pₒᵤₜ⁽⁰⁾ (from the second iteration)

Here, Pᵢₙ⁽¹⁾ and Pₒᵤₜ⁽⁰⁾ are expressed as Equation 13. Equation 13
where \mathring{X} denotes a convolution, P₀ denotes a density of the initial message u₀ which is obtained from the channel output, and Pₒᵤₜ⁽⁰⁾ denotes a density of extrinsic information

$${E}^{( 0 )} = {\sum }_{i = 1}^{{d}_{v}^{( 0 )}} {u}_{i}^{( 0 )}$$

which is forwarded from a first LPDC decoder. The case of the parity node is expressed as Equation 14.
P_{v,par}⁽¹⁾=P₀ (in the first iteration) Equation 14
P_{v,par}⁽¹⁾=P₀\mathring{X}Pᵢₙ⁽¹⁾ (from the second iteration)

Thus, because the probabilities that a certain edge is connected with an information node and with an parity node are r and 1−r, respectively, the probability density Pᵥ⁽¹⁾ is expressed as Equation 15.
Pᵥ⁽¹⁾=rP_{v,inf}⁽¹⁾+(1−r)P_{v,par}⁽¹⁾ Equation 15

Hereinafter, density evolution for an irregular LDPC code of the second LDPC decoder will be described.

The probability density Pᵥ⁽¹⁾ of a message v transmitted from a certain variable node to a check node is found as Equation 16.
Pᵥ⁽¹⁾=P₀ (in the first iteration) Equation 16
Pᵥ⁽¹⁾=P₀\mathring{X}|λ_{inf}⁽¹⁾(Pᵤ⁽¹⁾)\mathring{X}w⁽⁰⁾(Pᵤ⁽⁰⁾)+λₚₐᵣ⁽¹⁾(Pᵤ⁽¹⁾)| (from the second iteration)

Here, ω⁽⁰⁾, λ_{inf}⁽¹⁾ and λₚₐᵣ⁽¹⁾ are expressed as Equation 17.

$$\begin{matrix}{ω}^{( 0 )} ( {P}_{u}^{( 0 )} ) = {\sum }_{i = 2}^{{d}_{v}^{( 0 ) max}} {ω}_{i}^{( 0 )} {⊗}^{i} {P}_{u}^{( 0 )} \\ {λ}_{inf}^{( 1 )} ( {P}_{u}^{( 1 )} ) = {\sum }_{i > {k}_{0}^{( 1 )}}^{{d}_{v}^{( 1 ) max}} {λ}_{i}^{( 1 )} {⊗}^{i - 1} {P}_{u}^{( 1 )} + {λ}_{{k}_{0}^{( 1 )}}^{( 1 )} {α}^{( 1 )} ( {⊗}^{{k}_{0}^{( 1 )} - 1} {P}_{u}^{( 1 )} ) \\ {λ}_{par}^{( 1 )} ( {P}_{u}^{( 1 )} ) = {\sum }_{i < {k}_{0}^{( 1 )}}^{{k}_{0}^{( 1 )} - 1} {λ}_{i}^{( 1 )} {⊗}^{i - 1} {P}_{u}^{( 1 )} + \\ {λ}_{{k}_{0}^{( 1 )}}^{( 1 )} ( 1 - {α}^{( 1 )} ) ( {⊗}^{{k}_{0}^{( 1 )} - 1} {P}_{u}^{( 1 )} )\end{matrix} \qquad Equation 17$$

Here, ωᵢ⁽⁰⁾ (i.e., the total number of the information nodes having a degree of i/the total number of the information nodes), a node distribution, is found from the following degree distribution. Since the variable nodes consists of information nodes and parity nodes, and only information nodes in one code are connected to information nodes in the other code, it is necessary to define a new fraction as follows.

The degree distributions of the variable and check nodes having a code 0 are expressed as Equation 18.

$$\begin{matrix}{λ}^{( 0 )} ( x ) = {\sum }_{i \geq 1} {λ}_{i}^{( 0 )} {x}^{i - 1} , {ρ}^{( 0 )} ( x ) = {\sum }_{i \geq 1} {ρ}_{i}^{( 0 )} {x}^{i - 1} \\ \int {λ}^{( 0 )} ≡ {\sum }_{i} \frac{{λ}_{i}^{( 0 )}}{i} = {\sum }_{i} {N}_{i} / E = n / E\end{matrix} \qquad Equation 18$$

where Nᵢ denotes the number of nodes having a degree of i, n denotes the number of total nodes, and E denotes the number of total edges. A fraction of the node having a degree of i is expressed as Equation 19.

$${f}_{i}^{( 0 )} ≡ \frac{{λ}_{i}^{( 0 )}}{i \int {λ}_{( 0 )}} = \frac{{N}_{i}}{n} \qquad Equation 19$$

ω₁ ⁽⁰⁾ is determined from fᵢ⁽⁰⁾ as follows. It is assumed that a code 0 and a code 1 have the identical code rate of r, and that variable nodes with low degrees are preferentially are assigned as the parity nodes.

When

$${S}_{k} = {\sum }_{i = 1}^{k} {f}_{i}^{( 0 )} ,$$

denoting the smallest value of k satisfying the relation of Sₖ≧(1−r) be k₀⁽⁰⁾, the following Equation 20 may be obtained.

$$\begin{matrix}{ω}_{i}^{( 0 )} = \frac{{f}_{i}^{( 0 )}}{r} , ( i > {k}_{0}^{( 0 )} ) \\ {ω}_{{k}_{0}^{( 0 )}}^{( 0 )} = \frac{{S}_{{k}_{0}^{( 0 )}} - ( 1 - r )}{r} , ( i = {k}_{0}^{( 0 )} ) \\ {ω}_{i}^{( 0 )} = 0 , ( i < {k}_{0}^{( 0 )} )\end{matrix} \qquad Equation 20$$

Here, {ωᵢ⁽⁰⁾} represents these degree distribution when considering only the information nodes. It can be seen from Equation 20 that all of the variable nodes having a degree of i>k₀⁽⁰⁾ as well as some of the variable nodes having a degree of k₀⁽⁰⁾ are the information nodes. Especially, it can be seen that among the variable nodes having the degree of k₀⁽⁰⁾, the fraction of the information nodes is

$${α}^{( 0 )} = \frac{{S}_{{k}_{0}^{( 0 )}} - ( 1 - r )}{{f}_{{k}_{0}^{( 0 )}}} ,$$

and the fraction of the parity nodes is 1−α⁽⁰⁾. Likewise, in the case of the code 1, {ωᵢ⁽¹⁾} and α⁽¹⁾ may be obtained from the variable node degree distribution of the code 1.

A probability density Pᵤ of u according to the message update of the check node may be calculated on the basis of On the Design of Low-Density Parity-Check Codes within 0.0045 dB of the Shannon Limit, IEEE Commun. Lett., Vol. 5, No 2, February 2001, S. - Y. Chung, D. Forney, T. J. Richardson, and R. Urbanke, and is as follows.

Q(w) denotes a quantized message of w and is defined as Equation 21.

$$Q ( w ) = \{ \begin{matrix}⌊ \frac{w}{Δ} + \frac{1}{2} ⌋ \cdot Δ , & ( w \geq \frac{Δ}{2} ) \\ ⌈ \frac{w}{Δ} - \frac{1}{2} ⌉ \cdot Δ , & ( w \leq - \frac{Δ}{2} ) \\ 0 , & otherwise\end{matrix} \qquad Equation 21$$

where Q denotes a quantization operator, Δ denotes a quantization interval, |x| refers to the greatest integer which is not greater than x, and |x| refers to the smallest integer which is not smaller than x. The quantized message of uᵢ is represented by \overline{u}ᵢ. That is, \overline{u}ᵢ=Q(uᵢ).

The probability density function of the quantized message \overline{w} is defined as P_{w}[k]=Pr(\overline{w}=kΔ) (where, k denotes an integer).

A function with two input variables as in Equation 22 is introduced.

$$P ( a , b ) = Q ( 2 {tanh}^{- 1} ( tanh \frac{a}{2} tanh \frac{b}{2} ) ) \qquad Equation 22$$

A quantized check message is obtained in a form expressed by Equation 23 using the above function.
\overline{u}=R(v₁,R(v₂, . . . , R(v_{d}_{_{c}}_{-2,}v_{d}_{_{c}}₋₁) . . . )) Equation 23

When c=R(a,b), the probability density function P_{c} of c may be obtained by Equation 24.

$${P}_{c} [ k ] = {\sum }_{( i , j ) : k Δ = R ( i Δ , j Δ )} {P}_{a} [ i ] {P}_{b} [ j ] \qquad Equation 24$$

When the above equation is defined as P_{c}=f(Pₐ,P_{b}), the probability density function Pᵤ of u may be obtained by Equation 25.
Pᵤ=f(Pᵥ,f(Pᵥ, . . . , f(Pᵥ,Pᵥ), . . . )) Equation 25

In the case of the second LDPC decoder, the probability density function Pᵤ⁽¹⁾ of u is obtained by Equation 26
Pᵤ⁽¹⁾=f(Pᵥ⁽¹⁾,f(Pᵥ⁽¹⁾, . . . , f(Pᵥ⁽¹⁾,Pᵥ⁽¹⁾), . . . )) Equation 26

Hereinafter, density evolution for a regular LDPC code of the first LDPC decoder will be described.

It is assumed that the variable node of the first LDPC decoder has a degree of d⁽⁰⁾ᵥ and is connected to the variable node of the second LDPC decoder having a degree of d⁽¹⁾ᵥ, wherein an interleaver lies between the first and second decoders, a probability density Pᵥ⁽⁰⁾ of a message v transmitted from the variable node to a check node is found as Equation 27.
P_{v,inf}⁽⁰⁾=P₀\mathring{X}Pₒᵤₜ⁽¹⁾ (first iteration) Equation 27
P_{v,inf}⁽⁰⁾=P₀\mathring{X}Pᵢₙ⁽⁰⁾\mathring{X}Pₒᵤₜ⁽¹⁾ (from the second iteration)
Pᵢₙ⁽⁰⁾=P₁⁽⁰⁾\mathring{X} . . . \mathring{X}P_{d}_{ᵥ}_{⁽¹⁾}₋₁⁽⁰⁾
Pₒᵤₜ⁽¹⁾=P₁⁽¹⁾\mathring{X} . . . \mathring{X}P_{d}_{ᵥ}_{⁽⁰⁾}⁽¹⁾

where Pₒᵤₜ⁽¹⁾ denotes the density of extrinsic information

$${E}^{( 1 )} = {\sum }_{i = 1}^{{d}_{v}^{( 1 )}} {u}_{i}^{( 1 )}$$

outputted by the second LDPC decoder. In the case of the parity nodes, Pᵥ⁽⁰⁾ is expressed as Equation 28.
P_{v,par}⁽⁰⁾=P₀ (first iteration) Equation 28
P_{v,par}⁽⁰⁾=P₀\mathring{X}Pᵢₙ⁽⁰⁾ (from the second iteration)

Thus, because the probability that a certain edge is connected to one of the information nodes and one of the parity nodes are r and 1−r, respectively, the following Equation 29 may be obtained.
Pᵥ⁽⁰⁾=rP_{v,inf}⁽⁰⁾+(1−r)P_{v,par}⁽⁰⁾ Equation 29

Subsequently, density evolution method for an irregular LDPC code of the first LDPC decoder will be described.

The probability density Pᵥ⁽⁰⁾ of a message v transmitted from a certain variable node to a check node is found as Equation 30.

$${P}_{v}^{( 0 )} = ( {λ}_{{k}_{0}^{( 0 )}}^{( 0 )} {α}^{( 0 )} + {\sum }_{i > {k}_{0}^{( 0 )}}^{{d}_{v}^{max}} {λ}_{i}^{( 0 )} ) {P}_{0} ⊗ {w}^{( 1 )} ( {P}_{u}^{( 1 )} ) + ( {λ}_{{k}_{0}^{( 0 )}}^{( 0 )} ( 1 - {α}^{( 0 )} ) + {\sum }_{i < {k}_{0}^{( 0 )}}^{{k}_{0}^{( 0 )} - 1} {λ}_{i}^{( 0 )} ) {P}_{0} ( first iteration ) {P}_{v}^{( 0 )} = {P}_{0} ⊗ ⌊ {λ}_{inf}^{( 0 )} ( {P}_{u}^{( 0 )} ) ⊗ {w}^{( 1 )} ( {P}_{u}^{( 1 )} ) + {λ}_{par}^{( 0 )} ( {P}_{u}^{( 0 )} ) ⌋ ( from the second iteration ) \qquad Equation 30$$

Here, ω⁽¹⁾, λ_{inf}⁽⁰⁾ and λₚₐᵣ⁽⁰⁾ are expressed by Equation 31.

$$\begin{matrix}{ω}^{( 1 )} ( {P}_{u}^{( 0 )} ) = {\sum }_{i = 2}^{{d}_{v}^{( t ) max}} {w}_{i}^{( 1 )} {⊗}^{i} {P}_{u}^{( 1 )} , \\ {λ}_{inf}^{( 0 )} ( {P}_{u}^{( 0 )} ) = {\sum }_{i > {k}_{0}^{( 0 )}}^{{d}_{v}^{( 0 ) max}} {λ}_{i}^{( 0 )} {⊗}^{i ⋯ 1} {P}_{u}^{( 0 )} + {λ}_{{k}_{0}^{( 0 )}}^{0} {α}^{( 0 )} ( {⊗}^{{k}_{0}^{( 0 )} - 1} {P}_{u}^{( 0 )} ) , \\ {λ}_{par}^{( 0 )} ( {P}_{u}^{( 0 )} ) = {\sum }_{i < {k}_{0}^{( 0 )}}^{{k}_{0}^{( 0 )} - 1} {λ}_{i}^{( 0 )} {⊗}^{i ⋯ 1} {P}_{u}^{( 0 )} + {λ}_{{k}_{0}^{( 0 )}}^{( 0 )} ( 1 - {α}^{( 0 )} ) ( {⊗}^{{k}_{0}^{( 0 )} - 1} {P}_{u}^{( 0 )} )\end{matrix} \qquad Equation 31$$

The probability density function Pᵤ⁽⁰⁾ according to the message update at the check nodes may be calculated on the basis of On the Design of Low-Density Parity-Check Codes within 0.0045 dB of the Shannon Limit, IEEE Commun. Lett., Vol. 5, No 2, February, 2001, S. - Y. Chung, D. Forney, T. J. Richardson, and R. Urbanke, and be obtained as Equation 32.
Pᵤ⁽⁰⁾=f(Pᵥ⁽⁰⁾,f(Pᵥ⁽⁰⁾, . . . , f(Pᵥ⁽⁰⁾,Pᵥ⁽⁰⁾), . . . )) Equation 32

4. Gaussian-approximation density evolution of the parallel concatenated LDPC code

First, Gaussian-approximation density evolution for a regular LDPC code of the second LDPC decoder will be described as follows.

In the first LDPC decoder, extrinsic information on a variable node having a degree of d is calculated as Equation 33.

$${E}^{( 0 )} = {\sum }_{i = 1}^{d} {u}_{i}^{( 0 )} \qquad Equation 33$$

where, uᵢ⁽⁰⁾ is a message which is forwarded from a check node connected within a code 0. The second LDPC decoder receives \tilde{L} and

$${E}^{( 0 )} = {\sum }_{i = 0}^{d} {u}_{i}^{( 0 )} .$$

Here, the information nodes of the two codes are connected to each other with a random permutation interposed therebetween. Thus, each information node in the second LDPC decoder receives, on average, the extrinsic information expressed by Equation 34 by virtue of an action of the random permutation.

$$E [ {E}^{( 0 )} ] = {\sum }_{k}^{{d}_{b}^{( 0 ) max}} {w}_{k}^{( 0 )} \times {\sum }_{i = 1}^{k} E [ {u}_{i}^{( 0 )} ] , {{\sum }_{k}}^{{d}^{( 0 ) max}} {w}_{k}^{( 0 )} = 1 \qquad Equation 34$$

On applying the Gaussian-approximation to the second LDPC decoder, the mean of a Gaussian distribution is expressed by Equation 35.
mᵥ_{⁽¹⁾}_{,i}^{(l)}=mᵤ_{₀}_{⁽¹⁾}+(i−1)mᵤ_{⁽¹⁾}^{(l-1)}+m_{E[E}_{⁽⁰⁾}_{]} Equation 35

where 1 is the iteration number. Under the assumption of ideal random interleaving, in the case of a regular code, all of uᵢ⁽⁰⁾ have the identical distribution. Thus, the following Equation 36 may be obtained.
m_{E[E}_{⁽⁰⁾}_{]}=dᵥ⁽⁰⁾mᵤ⁽⁰⁾ Equation 36

Next, Gaussian-approximation density evolution for an irregular LDPC code of the second LDPC decoder will be described.

In the case of the irregular code, the distribution of uᵢ⁽⁰⁾ depends on the degree of each check node as Equation 37.

$${m}_{E [ {E}^{( 0 )} ]} = {\sum }_{i}^{{d}_{v}^{( 0 ) max}} {w}_{i}^{( 0 )} \times i \times {m}_{u}^{( 0 )} \qquad Equation 37$$

where wᵢ⁽⁰⁾ denotes the fraction of a variable node having a degree of i among the variable nodes belonging to the information part. In the case of the information node, the extrinsic information is added as Equation 38.
mᵥ_{⁽¹⁾}_{,i}⁽¹⁾=mᵤ_{₀}_{⁽¹⁾} (first iteration) Equation 38

$${m}_{{v}^{( 1 )} , i}^{( l )} = {m}_{{u}_{0}^{( 1 )}} + ( i - 1 ) {m}_{{u}^{( 1 )}}^{( i - 1 )} + {\sum }_{i}^{{d}_{c}^{( 0 ) max}} \times i \times {m}_{{u}^{( 0 )}}$$

from the second iteration)

In the case of the parity node, it is expressed, without extrinsic information, as Equation 39.
mᵥ_{⁽¹⁾}_{,i}⁽¹⁾=mᵤ_{₍₀₎}_{⁽¹⁾} (first iteration) Equation 39
mᵥ_{⁽¹⁾}_{,i}⁽¹⁾=mᵤ_{₀}_{⁽¹⁾}+(i−1)mᵤ_{⁽¹⁾}^{(l-1)} (from the second iteration)

Among any variable nodes having a degree of i=i_{b}, some belong to the information node portion and the others belong to the parity node portion. These variable nodes are called boundary variable nodes. When both the code rate and the degree distribution of variable nodes are given, the degree of the boundary variable nodes and the fractions of the information nodes and the parity node portions among the boundary variable nodes can be determined. Such fraction of information nodes portion among boundary variable nodes is defined as α. As in Equation 40, among the whole variable nodes, the two portions of the boundary variable nodes, i.e., the information node portion and the parity node portion are defined.
λᵢ_{_{b}}ᵢ=λᵢ_{_{b}}α, λᵢ_{_{b}}ₚ=λᵢ_{_{c}}(1−α) Equation 40

Then, when the mean for the degree distribution of the variable node is taken, the following Equation 41 may be obtained.

$${m}_{v}^{( l \div 1 )} = {\sum }_{i \neq {i}_{b}}^{{d}_{v}^{max}} {λ}_{i} {m}_{{v}^{( 1 )}}^{( l )} + {λ}_{{i}_{b} , i} {I}_{{v}^{( 1 )} , {i}_{b}}^{( l )} + {λ}_{{i}_{b} , p} {P}_{{v}^{( 1 )} , {i}_{b}}^{( l )} , {λ}_{{i}_{b} , i} + {λ}_{{i}_{b} , p} = {λ}_{{i}_{b}} \qquad Equation 41$$

where Iᵥ_{⁽¹⁾}_{,i}_{_{b}}⁽¹⁾ and Pᵥ_{⁽¹⁾}_{,i}_{_{b}}^{(l)} are the Gaussian means of messages forwarded from the information and parity nodes having a degree of i_{b}.

An expression for mᵤ can be obtained by applying the Gaussian approximation to u. First, the expectation of tan h (v/2) over degree distributions of variable nodes may be obtained as Equation 42.

$$E [ tanh \frac{v}{2} ] = {\sum }_{i}^{{d}_{v}^{max}} P ( i ) \cdot E [ tanh ( \frac{{v}_{i}}{2} ) ] \qquad Equation 42$$

In Equation 42, assuming that P(i)=λᵢ where λᵢ denotes the fraction of variable nodes having a degree of i, the following Equation 43 may be obtained.

$$E [ tanh \frac{v}{2} ] = \int tanh ( \frac{v}{2} ) f ( v ) ⅆ v \qquad Equation 43$$

Here, the probability density of v is expressed by Equation 44.

$$f ( v ) = {\sum }_{i \neq {i}_{b}}^{{d}_{v}^{max}} \frac{{λ}_{i}}{\sqrt{4 {π m}_{v , i}}} exp [ \frac{- {( v - {m}_{v , i} )}^{2}}{4 {m}_{v , i}} ] + \frac{{λ}_{{i}_{b} , i}}{\sqrt{4 π I}} exp [ \frac{- {( v - I )}^{2}}{4 I} ] + \frac{{λ}_{{i}_{b} , p}}{\sqrt{4 π P}} exp [ \frac{- {( v - P )}^{2}}{4 P} ] \qquad Equation 44$$

Thus, the following Equation 45 may be obtained.

$$\begin{matrix}E [ tanh \frac{v}{2} ] = {\sum }_{i}^{{d}_{v}^{max}} \frac{{λ}_{i}}{\sqrt{4 {π m}_{v , i}}} \int tanh ( \frac{v}{2} ) \\ exp [ \frac{- {( v - {m}_{v , i} )}^{2}}{4 {m}_{v , i}} ] ⅆ v + \\ \int tanh ( \frac{v}{2} ) \frac{{λ}_{{i}_{b} , i}}{\sqrt{4 π I}} exp [ \frac{- {( v - I )}^{2}}{4 I} ] ⅆ v + \\ \int tanh ( \frac{v}{2} ) \frac{{λ}_{{i}_{b} , p}}{\sqrt{4 π P}} exp [ \frac{- {( v - P )}^{2}}{4 P} ] ⅆ v \\ E [ tanh \frac{{v}^{( l )}}{2} ] = 1 - {\sum }_{i \neq {i}_{b}}^{{d}_{i}} {λ}_{i} ϕ ( {m}_{v , i}^{( l )} ) - {λ}_{{i}_{b} , i} ϕ ( {I}^{( l )} ) - \\ {λ}_{{i}_{b} , i} ϕ ( {P}^{( l )} )\end{matrix} \qquad Equation 45$$

Here, on applying a check node update rule to the check node having a degree of d_{c}−1, the following Equation 46 may be obtained.
tan h u/2=tan h v₁/2 tan h v₂/2 . . . tan h v _{d}_{_{c}}₋₁/2 Equation 46

Thus, when the average is taken using the probability density functions of u and vᵢ, all of vᵢ have the identical probability density function. Thereby, the following Equation 47 may be obtained.

$$E [ tanh \frac{u}{2} ] = {E [ tanh \frac{v}{2} ]}^{{d}_{c} - 1} \qquad Equation 47$$

Here, assuming that u also has a density of a Gaussian form, the following Equation 48 may be obtained.

$$E [ tanh \frac{u}{2} ] = 1 - ϕ ( {m}_{u , {d}_{c} - 1} ) \qquad Equation 48$$

Thus, a mean value m_{u,j} of the check node having a degree of j is given as Equation 49.

$${m}_{u , j}^{( l )} = {ϕ}^{- 1} ( 1 - {[ 1 - {\sum }_{i \neq {i}_{b}}^{{d}_{i}} {λ}_{i} ϕ ( {m}_{v , i}^{( l )} ) - {λ}_{{i}_{b} , i} ϕ ( {I}^{( l )} ) - {λ}_{{i}_{b} , i} ϕ ( {P}^{( l )} ) ]}^{j - 1} ) \qquad Equation 49$$

The probability density of a message u transmitted to each variable node is expressed as Equation 50 by taking the mean of the degree distribution of the check node.

$${m}_{u}^{( l )} = {\sum }_{j = 1}^{{d}_{c}^{max}} {ρ}_{j} {ϕ}^{- 1} ( 1 - {[ 1 - {\sum }_{i \neq {i}_{b}}^{{d}_{i}} {λ}_{i} ϕ ( {m}_{v , i}^{( l )} ) - {λ}_{{i}_{b} , i} ϕ ( {I}^{( l )} ) - {λ}_{{i}_{b} , i} ϕ ( {P}^{( l )} ) ]}^{j - 1} ) \qquad Equation 50$$

Next, Gaussian-approximation density evolution of the first LDPC decoder will be described.

The mean values of probability density functions of v and u for the first LDPC decoder can be obtained, similarly to the second LDPC decoder. In the case of the information node, extrinsic information is added as Equation 5 1.

$${m}_{{v}^{{( 0 )}_{, i}}}^{( l )} = {m}_{{u}_{0}^{( 0 )}} + {\sum }_{i}^{{d}_{v}^{( 1 )} max} {w}_{i}^{( 1 )} \times i \times {m}_{{u}^{( 1 ) }} ( first iteration ) \\ {m}_{{v}^{{( 0 )}_{, i}}}^{( l )} = {m}_{{u}_{0}^{( 1 )}} + ( i - 1 ) {m}_{{u}_{0}^{( 1 )}}^{( l - 1 )} + {\sum }_{i}^{{d}_{v}^{( 1 )} max} {w}_{i}^{( 1 )} \times i \times {m}_{{u}^{( 1 )}} \\ ( from the second iteration ) \qquad Equation 51$$

In the case of the parity nodes, it is given without the extrinsic information as Equation 52.

$${m}_{{v}^{{( 0 )}_{, i}}}^{( l )} = {m}_{{u}_{0}^{( 0 :}} ( first iteration ) \\ {m}_{{v}^{( 0 )} , i}^{( l )} = {m}_{{u}_{{0}^{( 0 )}}} + ( i - 1 ) {m}_{{u}^{( 0 )}}^{( l - 1 )} \\ ( from the second iteration ) \qquad Equation 52$$

As in the second LDPC decoder, mᵤ⁽¹⁾ is found.

5. Results of degree distribution optimization using Gaussian approximation

The following shows an example of the parallel concatenated code obtained by applying the channel capacity analysis method of the aforementioned parallel concatenated code. Here, the concatenated code was composed of two component codes having an identical code rate. The length of the information block is K, the length of the first or second parity block is M, and the length of the codeword is K+2M. The code rate R of the concatenated code could be expressed in terms of a code rate r of the component code as Equation 53.

$$R = \frac{K}{K + 2 M} = \frac{r}{2 - r} , r = \frac{K}{N} , N = k + M \qquad Equation 53$$

The degree distribution optimized using Gaussian approximation density evolution and an optimization algorithm is represented in table 1. A genetic algorithm is used in search of the optimal degree distribution. The optimization of degree distribution is performed under the constraint of the maximum variable degree dₘₐₓ. The optimized degree distributions with dₘₐₓ=10 are shown for the code rates of 1/2, 1/3, 1/4, 1/5 and 1/6.

TABLE 1

| | Code rate | | | | |
|---|---|---|---|---|---|
| | ½ | ⅓ | ¼ | ⅕ | ⅙ |
| | Code rate of component code | | | | |
| | ⅔ | ½ | ⅖ | ⅓ | 2/7 |
| λ₂⁽⁰⁾ | 0.724555 | 0.679308 | 0.675997 | 0.722409 | 0.619296 |
| λ₃⁽⁰⁾ | | | | 0.002373 | |
| λ₄⁽⁰⁾ | | | | 0.001311 | 0.000368 |
| λ₅⁽⁰⁾ | | | | 0.000023 | |
| λ₆⁽⁰⁾ | | 0.000035 | | 0.001128 | |
| λ₇⁽⁰⁾ | | | | 0.002731 | |
| λ₈⁽⁰⁾ | | 0.000128 | | 0.002994 | 0.001722 |
| λ₉⁽⁰⁾ | | 0.000305 | | 0.003787 | 0.000682 |
| λ₁₀⁽⁰⁾ | 0.275445 | 0.320224 | 0.324003 | 0.263246 | 0.377932 |
| ρ₃⁽⁰⁾ | | | | 0.120201 | |
| ρ₄⁽⁰⁾ | | | 0.444784 | 0.879799 | 0.968917 |
| ρ₅⁽⁰⁾ | | 0.575981 | 0.555216 | | 0.031083 |
| ρ₆⁽⁰⁾ | | 0.424019 | | | |
| ρ₇⁽⁰⁾ | 0.276674 | | | | |
| ρ₈⁽⁰⁾ | 0.723326 | | | | |
| λ₂⁽¹⁾ | 0.756817 | 0.317652 | 0.340650 | 0.315883 | 0.403279 |
| λ₃⁽¹⁾ | | 0.619871 | 0.549888 | 0.473498 | 0.539605 |
| λ₄⁽¹⁾ | | | | 0.009168 | 0.001709 |
| λ₅⁽¹⁾ | | 0.000009 | | 0.002623 | 0.005813 |
| λ₆⁽¹⁾ | | | | 0.000273 | |
| λ₇⁽¹⁾ | | 0.000338 | | 0.004874 | 0.016277 |
| λ₈⁽¹⁾ | | 0.000678 | | 0.013167 | 0.012198 |
| λ₉⁽¹⁾ | 0.006281 | 0.000414 | | 0.011166 | 0.006372 |
| λ₁₀⁽¹⁾ | 0.236902 | 0.061037 | 0.109462 | 0.169348 | 0.014797 |
| ρ₃⁽¹⁾ | | | | | 0.335385 |
| ρ₄⁽¹⁾ | | | 0.374807 | 0.522052 | 0.664615 |
| ρ₅⁽¹⁾ | | 0.576017 | 0.625193 | 0.477948 | |
| ρ₆⁽¹⁾ | | 0.423983 | | | |
| ρ₇⁽¹⁾ | 0.518867 | | | | |
| ρ₈⁽¹⁾ | 0.482233 | | | | |
| GA | 0.9450 | 1.2445 | 1.5340 | 1.7776 | 1.9985 |
| DE | 0.9394 | 1.2375 | 1.5167 | 1.7494 | 1.9375 |
| Shannon | 0.978694 | 1.296627 | 1.549594 | 1.766638 | 1.959823 |
| Limit | | | | | |

6. Simulation results of finite length parallel concatenated LDPC codes

The parity-check matrices used for component codes have the same dimension. In the generation of each parity-check matrix, a position of ‘1’ is randomly determined according to the degree distribution. A girth conditioning process, where the girth of each column is calculated and the mean girth of the whole columns is maximized, is applied to lower the error floor to the maximum extent. Then, for the parity-check matrix for each component code, columns having a low degree are preferentially assigned as the parity nodes. That is, the column weight of a parity node is less than or equal to the minimum column weight of the information node. For a construction of a parity-check matrix of a lower triangular form, the position where “1” was to be produced was limited to regions other than “0” shown in FIG. 4.

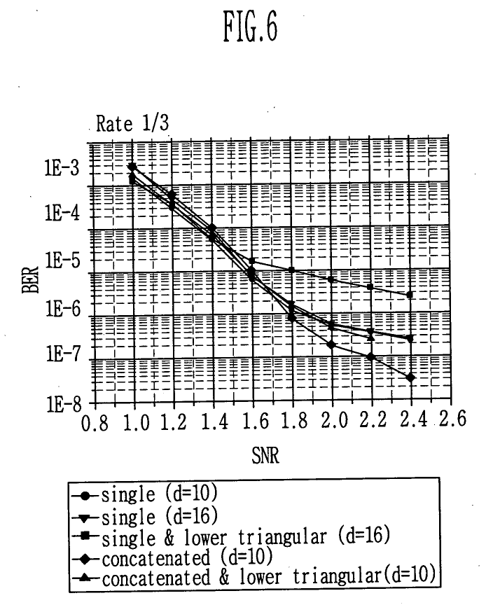

FIG. 5 is a graph showing simulation results on the assumption that an LDPC code having a code rate of 1/2 and a code word length of 1000 bits is subjected to BPSK modulation and is assigned an AWGN channel. All of single and concatenated codes have the variable node having the maximum degree of 10. For the single code, the degree distribution obtained by Richardson et al. was used. For the concatenated code, the results obtained from the Gaussian approximation shown in Table 1 were used. In the case of the single code, the parity-check matrix formed a code of a lower triangular form which allows a linear time encoding. It was found that, when compared to single and single lower triangular codes, the concatenated code had somewhat deteriorated performance at a signal to noise ratio (SNR) less than 2.0 dB and had comparable performance to the single lower triangular code at a signal to noise ratio (SNR) more than 2.2 dB. It should be noted that the concatenated code also enables the linear time encoding as the single lower triangular code. In FIG. 4, H₀ and H₁ refer to parity-check matrices of the first and second LDPC codes, respectively. I and Π(I) refer to information nodes of the parity-check matrices of the first and second LDPC codes, respectively. P0 and P1 refer to parity nodes of the parity-check matrices of the first and second LDPC codes, respectively.

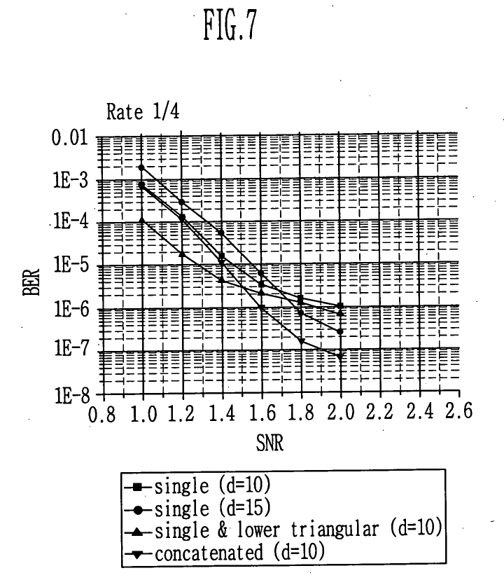

FIG. 6 is a graph showing simulation results on the assumption that an LDPC code having a code rate of 1/3 and a code word length of 1500 bits is subjected to BPSK modulation and is assigned an AWGN channel. For the single code, the degree distribution obtained by J. Hou et al. was used. For the concatenated code, the results obtained from the Gaussian approximation shown in Table 1 were used. For the single codes, the code with the maximum variable degree of 10 shows a little better performance in the low SNR region compared with the code with the variable node degree of 16. All of the concatenated codes have the maximum variable node degree of 10 and the degree distributions obtained from the Gaussian approximation shown in Table 1 was used. For single codes, the degree distribution obtained by Hou et al. was used. The degree distribution used by the Hou et al. is well disclosed in Performance Analysis and Code Optimization ofLow Density Parity-Check Codes on Rayleigh Fading Channels, IEEE J. Select. Areas Commun. Vol. 19, no. 5, pp. 924-934, May, 2001, J. Hou, P. H. Siegel, and L. B. Milstein. Although the concatenated code having the maximum variable degree of 10 was a little deteriorated in performance in a low SNR region when compared with the single code, the concatenated code shows much better performance in a high SNR region having about 1.7 dB or more. Especially, the concatenated code of the lower triangular form shows performance similar to the single code in the whole SNR regions. By contrast, it was found that the single code of the lower triangular form which had been formed to enable the linear time coding had considerably deteriorated in performance in the high SNR region. Furthermore, it was found that the concatenated code of the lower triangular form represented the low error floor, thus showing performance corresponding to that of the single code and simultaneously making it possible to rapidly perform the coding.

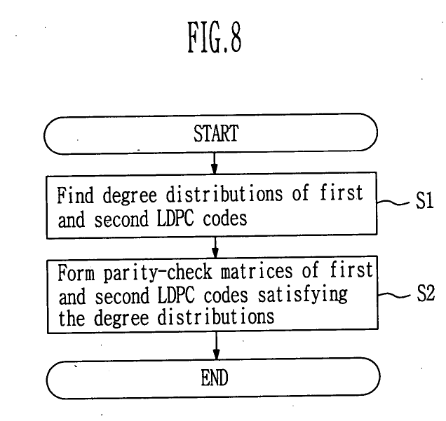

FIG. 7 is a graph showing simulation resuls on the assumption that an LDPC code having a code rate of 1/4 and a codeword length of 2000 bits is subjected to BPSK modulation and is assigned an AWGN channel. Both the single code and the concatenated code used the degree distribution results obtained by the Gaussian approximation shown in Table 1. The concatenated code shows better performance than the single code. Furthermore, the concatenated code of the lower triangular form to enable the linear time encoding shows better performance, compared with the single code.

Putting the aforementioned results together, when the code rate is low, the parallel concatenated codes shows better performance over single codes. Especially, because the parallel concatenated code enables the linear time coding without great deterioration in performance, it is more suitable than the single codes for high speed applications.

Hereinafter, the preferred embodiment of the present invention will be described with reference to the accompanying drawings. However, the embodiments of the present invention may be modified in various forms within the spirit or scope of the subject matter of the present invention, the scope of the present invention should not be construed as limited to the embodiments set forth herein. The embodiments of the present invention are to be provided to those ordinarily skilled in the art to fully convey the scope of the invention.

FIG. 8 is a flow chart showing a method of forming a parity-check matrix for a parallel concatenated LDPC code in accordance with one embodiment of the present invention.

Referring to FIG. 8, the method of forming the parity-check matrix for the parallel concatenated LDPC code includes steps of finding degree distributions of first and second LDPC codes (S1), and forming parity-check matrices of the first and second LDPC codes satisfying the degree distributions (S2).

In step S1 of finding the degree distributions, the degree distributions are obtained using performance measurement by the density evolution method. Further, in the density evolution method, a message forwarded from a variable node of the first LDPC code to a check node has a probability density reflecting that of extrinsic information outputted from the second LDPC code, and a message forwarded from a variable node of the second LDPC code to a check node has a probability density reflecting that of extrinsic information outputted from the first LDPC code. The first and second LDPC codes may have different degree distributions from or identical degree distribution to each other. Since the mathematical calculation of the probability densities of the messages, which are forwarded from the variable nodes of the first and second LDPC codes to the check nodes, has been previously described, the detailed description thereof would be omitted to avoid the repetition.

In step S2 of forming the parity-check matrices, the first and second parity-check matrices satisfying the degree distributions obtained in step S1 are formed. At this time, as the parity-check matrices are formed in a lower triangular form as shown in FIG. 4, the LDPC code may be easily coded without performance deterioration thereof.

As can be seen from the foregoing, the present invention makes it possible to form the parallel concatenated code having good performance in the low code rate when being compared to the single LDPC code. When individual component codes are formed in the lower triangular form such that the coding time is linearly proportional, the parallel concatenated LDPC code according to the present invention may have considerably good performance over the single code of the lower triangular form.

1. A method of forming a parity-check matrix for a parallel concatenated low density parity check (LDPC) code, wherein the parallel concatenated LDPC code is composed of a first LDPC code, a second LDPC code, and an interleaver connecting therebetween, the method comprising the steps of:
(a) finding a degree distribution of the first LDPC code and a degree distribution of the second LDPC; and
(b) forming the parity-check matrices of the first and second LDPC codes satisfying the degree distributions,
wherein in step (a), the degree distributions of the first and second LDPC codes are found using performance measurement by a density evolution method, and
wherein in the density evolution method, the probability density of a message forwarded from a variable node of the first LDPC code to a check node reflects a probability density of extrinsic information outputted from the second LDPC code, and the probability density of a message forwarded from a variable node of the second LDPC code to a check node reflects a probability density of extrinsic information outputted from the first LDPC code.

2. The method as set forth in claim 1, wherein:
the first and second LDPC codes are regular LDPC codes; and
the message v forwarded from the variable node of the first LDPC code to the check node has probability density Pᵥ⁽⁰⁾ which is calculated by the following equation:
Pᵥ⁽⁰⁾=rP_{v,inf}⁽⁰⁾+(1−r)P_{v,par}⁰⁾
where r, the code rate of the first LDPC code, is the probability that a certain edge is to be connected to an information node, 1−r is the probability that a certain edge is to be connected to a parity node, P_{v,inf}⁽⁰⁾ denotes thhe probability density of the message forwarded from an information variable node of the first LDPC code to a check node, and P_{v,par}⁽⁰⁾ denotes the probability density of the message forwarded from a parity variable node of the first LDPC code to a check node.

3. The method as set forth in claim 2, wherein the P_{v,inf}⁽⁰⁾ and P_{v,par}⁽⁰⁾ are calculated by the following equation:
P_{v,inf}⁽⁰⁾=P₀ (in the first iteration)
P_{v,inf}⁽⁰⁾=P₀\mathring{X}Pᵢₙ⁽⁰⁾\mathring{X}Pₒᵤₜ⁽¹⁾ (from the second iteration
P_{v,par}⁽⁰⁾P₀ (in the first iteration)
P_{v,par}⁽⁰⁾=P₀\mathring{X}Pᵢₙ⁽⁰⁾ (from the second iteration)
where \mathring{X} denotes a convolution, P₀ denotes the probability density of an initial message obtained from a channel output, Pₒᵤₜ⁽¹⁾ denotes the probability density of the extrinsic information forwarded from the second LDPC code, and Pᵢₙ⁽⁰⁾ denotes the probability density within the first LDPC code.

4. The method as set forth in claim 1,
wherein the first and second LDPC codes make use of an LDPC code which is an irregular LDPC code; and
wherein a message v forwarded from a variable node of a first LDPC decoder to a check node has probability density Pᵥ⁽⁰⁾ calculated by the following equation:
$$\begin{matrix}{P}_{v}^{( 0 )} = ( {λ}_{{k}_{0}^{( 0 )}}^{( 0 )} {a}^{( 0 )} + {\sum }_{i > {k}_{0}^{( 0 )}}^{{d}_{v}^{max}} {λ}_{i}^{( 0 )} ) {P}_{0} ⊗ {w}^{( 1 )} ( {P}_{u}^{( 1 )} ) + \\ ( {λ}_{{k}_{0}^{( 0 )}}^{( 0 )} ( 1 - {α}^{( 0 )} ) + {\sum }_{i < {k}_{0}^{( 0 )}}^{{k}_{0}^{( 0 )} - 1} {λ}_{i}^{( 0 )} ) {P}_{0 } ( in the first iteration ) \\ {P}_{v}^{( 0 )} = {P}_{0} ⊗ ⌊ {λ}_{inf}^{( 0 )} ( {P}_{u}^{( 0 )} ) ⊗ {w}^{( 1 )} ( {P}_{u}^{( 1 )} ) + {λ}_{par}^{( 0 )} ( {P}_{u}^{( 0 )} ) ⌋ \\ ( from the second iteration )\end{matrix}$$
where \mathring{X} denotes a convolution, P₀ denotes the probability density of an initial message received from a channel output, ωᵢ⁽¹⁾ refers to the node distribution of the information node of the second LDPC code (the total number of information nodes having a degree of i/the total number of information nodes), λ_{inf}⁽⁰⁾ refers to the degree distribution of the information node of the first LDPC code, and λₚₐᵣ⁽⁰⁾ refers to the degree distribution of the parity node of the first LDPC code.

5. The method as set forth in claim 4, wherein the node distribution of the information node of the second LDPC code, ωᵢ⁽¹⁾, is calculated by the following equation:
$$\begin{matrix}{ω}_{i}^{( 0 )} = \frac{{f}_{i}^{( 0 )}}{r} , & ( i > {k}_{0}^{( 0 )} ) \\ {ω}_{{k}_{0}^{( 0 )}}^{( 0 )} = \frac{{S}_{{k}_{0}^{( 0 )}} - ( 1 - r )}{r} , & ( i = {k}_{0}^{( 0 )} ) \\ {ω}_{i}^{( 0 )} = 0 , & ( i < {k}_{0}^{( 0 )} )\end{matrix}$$
where r denote the code rate, fᵢ⁽¹⁾ denotes the node distribution of the node of the second LDPC code (the number of nodes having a degree of i/the total number of nodes), Sₖ corresponds to
$${\sum }_{i = 1}^{k} {f}_{i}^{( 1 )} ,$$
and k₀⁽¹⁾ refers to a smallest integer k satisfying Sₖ≧(1−r) of the second LPDC code.

6. The method as set forth in claim 1,
wherein a message v forwarded from an information node of the first LDPC code to a check node has a probability density function which has a mean value mᵥ_{⁽⁰⁾}⁽¹⁾, calculated by the following equation:
$$\begin{matrix}\begin{matrix}{m}_{{v}^{( 0 )} , i}^{( l )} = {m}_{{u}_{0}^{( 0 )}} + {\sum }_{i}^{{d}_{v}^{( 1 )} max} {w}_{i}^{( 1 )} \times \\ i \times {m}_{{u}^{( 1 )}}\end{matrix} & ( in the first iteration ) \\ \begin{matrix}{m}_{{v}^{( 0 )} , i}^{( l )} = {m}_{{u}_{0}^{( 0 )}} + ( i - 1 ) {m}_{{u}^{( 0 )}}^{( l - 1 )} + \\ {\sum }_{i}^{{d}_{v}^{( 1 )} max} {w}_{i}^{( 1 )} \times i \times {m}_{{u}^{( 1 )}}\end{matrix} & ( from the second iteration )\end{matrix}$$
wherein a message v forwarded from a parity node to a check node has a probability density function which has a mean value mᵥ_{⁽⁰⁾}_{,i}⁽¹⁾ calculated by the following equation:
mᵥ_{⁽⁰⁾}_{,f}⁽¹⁾=mᵤ_{₀}⁽⁰⁾ (in the first iteration)
mᵥ_{⁽⁰⁾}_{,i}⁽¹⁾=mᵤ_{₀}_{⁽⁰⁾}+(i−1)mᵤ_{⁽⁰⁾}^{(l-1)} (from the second iteration)
where mᵤ refers to the mean value of the probability density function of a message u forwarded from a check node to a variable node, ωᵢ⁽¹⁾ refers to the node distribution of the information nodes of the second LPDC code (the total number of information nodes having a degree of i/the total number of information nodes).

7. The method as set forth in claim 1, wherein the parity-check matrices of the first and second LDPC codes are formed in lower triangular forms.

8. The method as set forth in claim 1, wherein the degree distribution found in step (a) satisfies any one selected from a plurality of degree distributions which are expressed in the following table.

| | Code rate | | | | |
|---|---|---|---|---|---|
| | ½ | ⅓ | ¼ | ⅕ | ⅙ |
| | Code rate of component code | | | | |
| | ⅔ | ½ | ⅖ | ⅓ | 2/7 |
| λ₂⁽⁰⁾ | 0.724555 | 0.679308 | 0.675997 | 0.722409 | 0.619296 |
| λ₃⁽⁰⁾ | | | | 0.002373 | |
| λ₄⁽⁰⁾ | | | | 0.001311 | 0.000368 |
| λ₅⁽⁰⁾ | | | | 0.000023 | |
| λ₆⁽⁰⁾ | | 0.000035 | | 0.001128 | |
| λ₇⁽⁰⁾ | | | | 0.002731 | |
| λ₈⁽⁰⁾ | | 0.000128 | | 0.002994 | 0.001722 |
| λ₉⁽⁰⁾ | | 0.000305 | | 0.003787 | 0.000682 |
| λ₁₀⁽⁰⁾ | 0.275445 | 0.320224 | 0.324003 | 0.263246 | 0.377932 |
| ρ₃⁽⁰⁾ | | | | 0.120201 | |
| ρ₄⁽⁰⁾ | | | 0.444784 | 0.879799 | 0.968917 |
| ρ₅⁽⁰⁾ | | 0.575981 | 0.555216 | | 0.031083 |
| ρ₆⁽⁰⁾ | | 0.424019 | | | |
| ρ₇⁽⁰⁾ | 0.276674 | | | | |
| ρ₈⁽⁰⁾ | 0.723326 | | | | |
| λ₂⁽¹⁾ | 0.756817 | 0.317652 | 0.340650 | 0.315883 | 0.403279 |
| λ₃⁽¹⁾ | | 0.619871 | 0.549888 | 0.473498 | 0.539605 |
| λ₄⁽¹⁾ | | | | 0.009168 | 0.001709 |
| λ₅⁽¹⁾ | | 0.000009 | | 0.002623 | 0.005813 |
| λ₆⁽¹⁾ | | | | 0.000273 | |
| λ₇⁽¹⁾ | | 0.000338 | | 0.004874 | 0.016277 |
| λ₈⁽¹⁾ | | 0.000678 | | 0.013167 | 0.012198 |
| λ₉⁽¹⁾ | 0.006281 | 0.000414 | | 0.011166 | 0.006372 |
| λ₁₀⁽¹⁾ | 0.236902 | 0.061037 | 0.109462 | 0.169348 | 0.014797 |
| ρ₃⁽¹⁾ | | | | | 0.335385 |
| ρ₄⁽¹⁾ | | | 0.374807 | 0.522052 | 0.664615 |
| ρ₅⁽¹⁾ | | 0.576017 | 0.625193 | 0.477948 | |
| ρ₆⁽¹⁾ | | 0.423983 | | | |
| ρ₇⁽¹⁾ | 0.518867 | | | | |
| ρ₈⁽¹⁾ | 0.482233 | | | | |
